(19) United States
(12) Patent Application Publication
(10) Pub. No.: US 2026/0002256 A1
(43) Pub. Date: Jan. 1, 2026

(54) METHOD FOR PRODUCING SILICON FILM AND SILICON FILM

(71) Applicants: NIPPON SHOKUBAI CO., LTD., Osaka (JP); HIROSHIMA UNIVERSITY, Hiroshima (JP)

(72) Inventors: Tetsuya YAMAMOTO, Osaka (JP); Takashi ABE, Osaka (JP); Tatsuhiko AKIYAMA, Osaka (JP); Akinobu TERAMOTO, Hiroshima (JP)

(73) Assignees: NIPPON SHOKUBAI CO., LTD., Osaka (JP); HIROSHIMA UNIVERSITY, Hiroshima (JP)

(21) Appl. No.: 18/879,400

(22) PCT Filed: Jun. 27, 2023
(86) PCT No.: PCT/JP2023/023750

§ 371 Date: Dec. 27, 2024

(30) Foreign Application Priority Data
Jun. 29, 2022 (JP) 2022-104744

(51) Int. Cl. C23C 16/24; C23C 16/04

(52) U.S. Cl. CPC C23C 16/24; C23C 16/045

(57) ABSTRACT

The object of the present invention is to provide a method for producing a silicon film having high uniformity of film thickness or high step coverage through reduction of the thermal history of a cyclic silane compound. The present invention relates to a method for producing a silicon film, including the steps of heating a substrate inserted into a reactor of a cold-wall type thermal CVD system, supplying the cyclic silane compound to the reactor, and forming the silicon film on the substrate.

### TECHNICAL FIELD

The present invention relates to a method for producing a silicon film using a CVD method and a silicon film.

### BACKGROUND ART

Silicon thin films (for example, amorphous silicon films and polycrystalline silicon films) used in semiconductors and electronic devices such as thin-film transistors and integrated circuits are formed from monosilane, a gaseous material, as a raw material by a chemical vapor deposition method (CVD method). However, in recent years, there has been an increasing demand for improving a deposition rate to produce larger quantities of silicon thin films, and there also have been increasing demands for low-temperature deposition applicable to complex device structures, and for deposition of uniform films on substrates including irregularities.

For example, Patent Document 1 discloses a method for forming an amorphous silicon deposition film through application of thermal energy to a cyclic silane compound in a gaseous state under ambient pressure. In Patent Document 1, it is required to heat a deposition chamber including a substrate and multiple preheating chambers located on a line that connects a raw material gas regulating chamber and a deposition chamber.

Patent Document 2 also discloses a method for chemically depositing silicon-containing epitaxial films on a substrate by introducing cyclohexasilane into a chamber and heating the chamber at a temperature in the range of from 400° C. to 750° C.

Further, Patent Document 3 discloses a method for forming a silicon-containing epitaxial film using a deposition gas containing a specific hydrogenated silane compound as the source of silicon at a temperature in the range of from 450° C. to 600° C.

### PRIOR ART DOCUMENTS

### Patent Documents

Patent Document 1: JP-B-115-000469
Patent Document 2: JP-A-2013-537705
Patent Document 3: JP-A-2015-053382

### SUMMARY OF THE INVENTION

### Problems to be Solved by the Invention

In each of the above Patent Documents 1 to 3, since the cyclic silane compound is heated not only in the deposition chamber containing the substrate but also in other devices, the thermal history of the cyclic silane compound is increased and thus the decomposition of the cyclic silane compound is progressed before being deposited on the substrate, making it difficult to form a silicon film with uniform film thickness (or a silicon film with high step coverage) on the substrate.

Against such backgrounds, it is an object of the present invention to provide a method for producing a silicon film having high uniformity of film thickness or high step coverage through reduction of the thermal history of the cyclic silane compound, and a silicon film.

### Solution to the Problems

[1] A method for producing a silicon film comprising the steps of:
   heating a substrate inserted into a reactor of a cold-wall type thermal CVD system;
   supplying a cyclic silane compound to the reactor; and
   forming the silicon film on the substrate.
[2] The method according to [1], wherein the cyclic silane compound and an inert gas are supplied to the reactor, and a volume of the inert gas supplied to the reactor is at least five times greater than a volume of the cyclic silane compound.
[3] The method according to [1] or [2], wherein the silicon film is formed with uniformity of film thickness distribution of from −10% to +10% on a substrate including trench shaped or hole shaped irregularities.
[4] The method according to [3], wherein the trench shaped or hole shaped irregularities have an aspect ratio of 30 or less.
[5] The method according to anyone of [1] to [4], wherein the substrate is heated at a heating temperature of from 200° C. to 600° C.
[6] The method according to any one of [1] to [5], wherein the reactor has a pressure inside the reactor of from 0.01 kPa to 50 kPa.
[7] The method according to any one of [1] to [6], wherein the cyclic silane compound filled in a container is vaporized and then supplied to the reactor.
[8] The method according to any one of [1] to [7], wherein the cyclic silane compound contains cyclopentasilane or cyclohexasilane.
[9] The method according to any one of [1] to [8], wherein the silicon film is heated at 600° C. or higher.
[10] A silicon film including a cyclic silane compound, wherein the silicon film has uniformity of film thickness of from −0.3 nm to +0.3 nm when the silicon film has a thickness of 0.5 nm or more and less than 3.0 nm, or the silicon film has uniformity of film thickness distribution of from −10% to +10% when the silicon film has a thickness of 3.0 nm or more.
[11] A silicon film including a cyclic silane compound, wherein the silicon film is formed on a substrate including trench shaped or hole shaped structure with irregularities, a ratio (A/B) of a silicon film thickness A on a sidewall at a depth of ¼t to a silicon film thickness B on a sidewall at a depth of ¾t is from 0.8 to 1.2 when a trench or hole has a depth of 0/t at a bottom and a depth of t/t at an upper edge,
[12] The silicon film according to [11], wherein the substrate including the irregularities has an aspect ratio of 30 or less.
[13] The silicon film according to any one of [10] to [12], wherein a full width at half maximum of a Raman spectrum peak in the range of from 510 cm⁻¹ to 530 cm⁻¹ is 3 cm⁻¹ or more and 10 cm⁻¹ or less when measured by laser Raman spectroscopy.

### Effects of the Invention

According to the present invention, the method for producing the silicon film having high uniformity of film thickness or high step coverage through reduction of the thermal history of the cyclic silane compound, and the silicon film can be provided.

### BRIEF DESCRIPTION OF DRAWINGS

FIG. 1 is a diagram illustrating an embodiment of a method for producing the silicon film of the present invention or an apparatus for producing the silicon film of the present invention.

FIG. 2 is a diagram illustrating an embodiment of a silicon film of the present invention formed on a substrate including irregularities.

FIG. 3 is a cross-sectional TEM image of an entire silicon film formed from cyclohexasilane as a raw material on the substrate including irregularities.

FIG. 4 is an enlarged view showing an upper part of the cross-sectional TEM image of the silicon film formed from cyclohexasilane as a raw material on the substrate including irregularities, as shown in FIG. 3.

FIG. 5 is an enlarged view showing a lower part of the cross-sectional TEM image of the silicon film formed from cyclohexasilane as a raw material on the substrate including irregularities, as shown in FIG. 3.

### DESCRIPTION OF EMBODIMENTS

### 1. Method for Producing Silicon Film

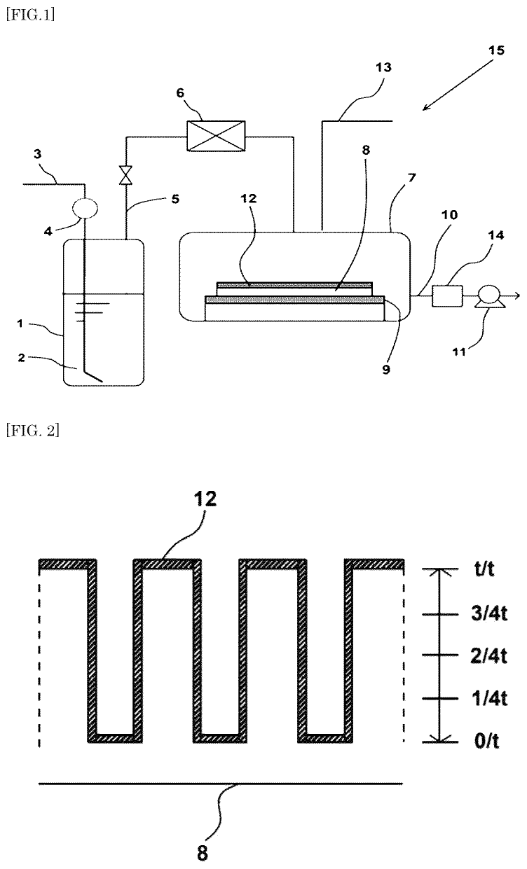

Hereinafter, description of one embodiment according to the method for producing the silicon film of the present invention will be given with reference to FIG. 1, and the present invention is not limited to the embodiment.

FIG. 1 is a schematic diagram of a system used to illustrate an exemplary embodiment of the method for producing the silicon film of the present invention. In the embodiment, a substrate 8 inserted into a reactor 7 of a cold-wall type thermal CVD system 15 is heated a cyclic silane compound 2 is supplied to the reactor 7, and a silicon film 12 is formed on the substrate 8.

In the present invention, a cold wall type thermal CVD system is a thermal CVD system in which only a substrate is heated without heating the reactor, and a heating device is installed in a part inside the reactor (the heating device is preferably installed at one side inside the reactor, for example near the bottom inside the reactor, and the volume of the unheated area inside the reactor is large), whereas a hot-wall type thermal CVD system is a thermal CVD system in which both of a reactor and a substrate are heated and a heating device is installed outside the reactor or throughout the entire interior of the reactor.

In the case of the hot-wall type thermal CVD system, the cyclic silane compound may be decomposed by heat because the thermal CVD system requires to heat a pipe for sending the cyclic silane compound to a reactor and the reactor. The heating causes the decomposition of the cyclic structure of the cyclic silane compound before it reaches to the substrate, and a deposited film may not have sufficient three-dimensional workability.

In contrast, in the case of the cold wall type thermal CVD, the cyclic silane compound filled in the reactor substantially need not to be heated by a heat source other than the substrate in the reactor, for example, the pipe for sending the cyclic silane compound to the reactor and the reactor substantially need not to be heated by a heat source, thereby making the heating temperature in this system significantly lower than the heating temperature in the hot-wall type thermal CVD system; therefore, the cyclic silane compound is not decomposed and can reach the substrate with its cyclic structure being maintained, and a deposited film having sufficient three-dimensional workability can be obtained.

The above “substantially need not to be heated” means that the gas (for example, raw material gas and carrier gas) supplied to the reactor is set at, for example, 100° C.) or lower (preferably 70° C. or lower, more preferably 50° C. or lower, and further preferably 35° C. or lower). A preferred system which can achieve the above “substantially need not to be heated” may be provided with a mild heating device to prevent liquefaction of gas supplied to the reactor (for example, at least one of a heating chamber and a pipe, and the temperature is preferably 26° C. or higher, and more preferably 28° C. or higher).

The cold wall type thermal CVD system 15 includes a raw material tank 1, an inert, gas introduction line 3 for bubbling connected to the raw material tank 1, a supply line 5 connecting the raw material tank and the reactor, pressure controllers 6 and 14, the reactor 7, the substrate 8, a substrate heater 9, an outlet 10 from the reactor, and an inert gas introduction line 13 for dilution.

More specifically, the raw material tank 1 is provided with the inert gas introduction line 3 for bubbling to bubble the cyclic silane compound 2 with the inert gas, and a mixed gas having a concentration determined by the vapor pressure of the cyclic silane compound is supplied to the reactor 7 via the pressure controller 6.

As illustrated in the diagram, the substrate 8, the substrate heater 9, a substrate holder (not illustrated), and the outlet 10 are installed inside the reactor 7, and the silicon film 12 can be formed on the substrate 8 by directly introducing the cyclic silane compound 2 (preferably cyclohexasilane) into the reactor 7 from the supply line 5. The pressure controller 14 and a vacuum pump 11 are connected to the reactor 7 illustrated in the diagram, in order to regulate the gas flow, thereby regulating the temperature and the pressure, if needed.

The present invention has the feature that the cyclic silane compound is not decomposed by heating in the raw material tank and the reactor (the thermal history of the cyclic silane compound is reduced), and the cyclic silane compound is heated only on the substrate in the reactor. As a result, the cyclic silane compound can be stably supplied to the reactor such that the cyclic silane compound does not contain a polymer and a cracked low boiling fraction generated therefrom by heat, enabling high speed deposition and low-temperature deposition by CVD method: therefore high step coverage can be achieved to form a silicon film with high purity.

The cyclic silane compound 2 preferably contains cyclopentasilane or cyclohexasilane, and more preferably cyclohexasilane from the viewpoint of stability as a compound.

When the cyclohexasilane is used as the cyclic silane compound, the cyclohexasilane may be produced by a conventionally known method, for example, (1) by coupling diphenyldichlorosilane with metal to form a six-membered ring, followed by halogenating and reducing the six-membered ring; (2) by reacting trichlorosilane as a halosilane, triphenyl phosphine, and N,N-diisopropylethylamine to form a cyclic halosilane neutral complex in which triphenylphosphine coordinates to dodecachlorocyclohexasilane with a six-membered ring, and subsequently reducing the cyclic halosilane neutral complex; or (3) by reacting trichlorosilane as a halosilane, an onium salt such as an ammonium salt or phosphonium salt, and a tertiary amine to obtain a salt of a cyclic halosilane compound, then treating the salt of a cyclic halosilane compound with a Lewis acid compound to obtain a cyclic halosilane compound, and reducing the cyclic halosilane compound. Further, cyclohexasilane after purification may be used to remove impurities from the viewpoint of forming a silicon film with high purity.

The content of the cyclohexasilane is preferably 97% by mass or more, more preferably 97.5% by mass or more, further preferably 98.0% by mass or more based on 100% by mass of the cyclic silane compound. The content as close to 100% by mass as possible is desired, and the content may be 99.9% by mass or less or 99.7% by mass or less.

The content may be determined on the basis of an area percentage obtained by gas chromatographic analysis.

The cyclohexasilane may be present together with a very little amount of metal originating from raw materials (for example, A1), and a metal content in a composition containing the cyclohexasilane and the metal is, for example, 1 ppm or less, preferably 500 ppb or less, more preferably 100 ppb or less, for example, 0.01 ppb or more, preferably 0.1 ppb or more, and more preferably 1 ppb or more based on a mass standard of the total metal content.

The metal content may be determined, for example, by ICP-mass spectrometry, ICP-atomic emission spectroscopy, or atomic absorption spectrometry.

The raw material tank 1 is recommended to be kept such that the cyclic silane compound 2 is prevented from undergoing thermal polymerization or photopolymerization and the cyclic silane compound 2 can be stably supplied to the reactor 7 via the supply line 5.

The cyclic silane compound 2 may be supplied to the reactor 7 by any one of the methods including a bubbling method, a baking method, and a direct gasification method, and these methods may be used in combination. However, when the cyclic silane compound is heated, the cyclic silane compound is desirably heated at a temperature equal to or lower than the temperature described below due to the risk of polymeric degradation.

If the cyclic silane compound 2 is heated, for example, the temperature of the cyclic silane compound 2 in the raw material tank 1 may be maintained at a temperature equal to or lower than a predetermined temperature, the cyclic silane compound 2 filled in the container (raw material tank 1) is preferably valorized and then transferred to the reactor 7, and the cyclic silane compound 2 filled in the container (raw material tank 1) is more preferably vaporized at a temperature equal to or lower than 70° C., and then transferred (sent) to the reactor 7.

The temperature may be maintained more preferably at 50° C. or lower, further preferably 45° C. or lower, and further more preferably 40° C. or lower. If the temperature is lowered excessively, the preventive effects against thermal polymerization and photopolymerization may become saturated, further, cooling to the temperature below the melting point may cause solidification, leading to difficulties in transportation. The lower limit of the temperature of the cyclic silane compound 2 is preferably 15° C. or higher, more preferably 18° C. or higher, and further preferably 20° C. or higher. The temperature is applied when the raw material tank 1 is depressurized and when the inert gas is supplied to the raw material tank 1, as described below.

When the reactor 7 is heated to the extent that the decomposition of the cyclic silane compound 2 does not occur, the temperature of the raw material tank 1 is preferably from room temperature to 100° C. or lower, more preferably 70° C. or lower, further preferably 50° C. or lower, and most preferably 40° C. or lower. The temperature of higher than 100° C. may cause decomposition of the cyclic structure of the cyclic silane compound 2 and thus a decrease in the purity of the cyclic silane compound 2 in the raw material tank 1, thereby failing to improve the uniformity of film thickness or step coverage. The temperature is particularly preferably 50° C. or lower from the viewpoint of three-dimensional workability.

The material of the raw material tank 1 is not particularly limited as long as the thermal polymerization and the photopolymerization of the cyclic silane compound 2 are not caused, and examples of the material include high strength, light-impermeable stable materials, specifically, iron, nickel, molybdenum, manganese, chromium, titanium, copper, aluminum, and alloys thereof. Specifically, stainless steel (SUS) is preferred as a material of the raw material tank 1.

The raw material tank 1 may have a light-shielding property or may include a light-shielding plate, if needed. The raw material tank 1 preferably has pressure resistance from the viewpoint of safe handling of the cyclic silane compound 2 with pyrophoric properties. The raw material tank 1 has pressure resistance of more preferably 0.05 MPa or more.

The raw material tank 1 is required to have an outlet equipped with at, least one valve illustrated by, for example, the supply line 5. In case where at least two valves are used, at least one of the at least two valves is preferably a pressure valve or a material filling valve, and at least one of the at least two valves is preferably a raw material supply valve. Further, the raw material tank 1 may have two or more outlets for tank cleaning.

The size of the raw material tank 1 is preferably from approximately 50 ml to 100 L, and more preferably from approximately 500 ml to 10 L. The shape of the raw material tank 1 is not particularly limited and is, for example, columnar, prismatic, or cylindrical shape.

The method for supplying the cyclic silane compound 2 from the raw material tank 1 to the reactor 7 is not limited to the bubbling method as shown in FIG. 1, and any supplying method with little thermal history is preferred. In an embodiment of the bubbling method illustrated in FIG. 1, the inert gas introduction line 3 for bubbling is installed on the upper part (in particular, on the upper surface) of the raw material tank 1, and the flow rate of the inert gas can be regulated by the flow controller 4. The connection location of the inert gas introduction line 3 for bubbling can be appropriately adjusted. The connection location thereof is preferably located below the liquid level of the cyclic silane compound 2, and preferably located at the very bottom (bottom surface) of the container (raw material tank 1). The pressure upon bubbling from the raw material tank 1 may be appropriately determined, and the pressure may be regulated by a pressure controller.

Examples of the inert gas include nitrogen, helium, neon, and argon. The inert gas is preferably nitrogen, helium, or argon, more preferably nitrogen or argon, and further preferably argon from the viewpoint of availability and cost.

The supply line 5 may be provided with the pressure controller 6 to reduce the pressure of the raw material tank 1 filled with the cyclic silane compound 2. The pressure of the raw material tank 1 is preferably from 0.01 kPa to 50 kPa, more preferably from 0.05 kPa to 20 kPa, and further preferably from 0.1 kPa to 10 kPa. If the pressure of the raw material tank 1 is more than 50 kPa, the cyclic silane compound 2 may not be vaporized in sufficient concentration.

Preferably, the supply line 5 supplies the cyclic silane compound 2 from the raw material tank 1 to the reactor 7 by the bubbling method. The bubbling method can be carried out by installing an appropriate inert gas introduction line 3 for bubbling in the raw material tank 1, other than the supply line 5. For bubbling, the flow controller 4 may be installed at an appropriate position (for example, on or upstream of the inert gas introduction line 3).

As a material of the supply line 5, any material known by use in the conventional art may be used, as long as the cyclic silane compound 2 can be supplied, and the material may be aluminum or stainless, both of which have corrosion-resistance. The structure of the supply line 5 is not particularly limited as long as the supply line 5 is an enclosed pipeline for transferring the raw material from the raw material tank 1 to the reactor 7. The temperature of the supply line 5 may be the same as the temperature described for the raw material tank 1.

The pressure controller 6 inserted into the supply line 5 is not essential in the present invention. The supply amount can be suitably controlled by appropriately controlling the flow rate and the pressure inside the reactor, and the supply amount of the cyclic silane compound 2 is preferably controlled by the pressure controller 6. The pressure controller 6 is inserted into the supply line 5 at any position between the raw material tank 1 and the reactor 7 as long as the pressure of the raw material tank 1 can be controlled.

In the present invention, the flow controller 4 preferably includes a flow sensor, a bypass, a flow control valve, and an electrical circuit. In the flow controller, the supplied raw material may be split into two streams including one leading to the flow sensor and the other leading to the bypass, and the electrical circuit may regulate the flow control valve to maintain appropriate flow rate. Examples of the flow control valve include a piezo actuator valve, a thermal actuator valve, and a solenoid actuator valve.

When the flow controller 4 is a throttling valve, the throttling valve is appropriately regulated preferably depending on the flow rate. For example, a sensor for measuring the liquid flow rate may be installed at an appropriate position inside the raw material tank 1, on the supply line 5, or inside the reactor 7, and the opening of the throttling valve may be regulated based on the signal from the sensor.

The chemical vapor deposition is not limited to the apparatus illustrated in FIG. 1 and the method using the apparatus, and any CVD method may be selected as long as the high speed deposition and the low temperature deposition can be carried out, and the silicon film with high step coverage and high purity can be formed. Among methods available, a low-pressure CVD method is preferred as the chemical vapor deposition. The low-pressure CVD method can prevent contamination of a foreign substance more efficiently during deposition, and increases the mean free path of a deposition gas, enabling further improvement in the uniformity of film thickness and step coverage.

The low-pressure CVD method is a chemical vapor deposition method in which a compound containing constituent elements of a desired deposit is supplied to a substrate as species having high vapor pressure together with the carrier gas and grows as amorphous, polycrystalline, and monocrystalline materials; the low-pressure CVD method is a chemical vapor deposition in which the main reaction is caused by thermal excitation and a gas phase pressure is lower than ambient, pressure (for example, less than 101 kPa). The reactor includes a substrate, a substrate heater, a carrier gas introduction line, an outlet, and a vacuum pump, and thermally decomposes the cyclic silane compound to deposit an amorphous silicon and polycrystalline silicon thin film on the substrate.

In the low-pressure CVD method, the type of the reacting furnace of the reactor may be, for example, a horizontal type, a vertical type, a cylindrical type, a continuous type, or a tubular type. For example, in the horizontal type, a substrate is horizontally placed, then gas is introduced horizontally to the substrate, and a Si-containing film is formed on the substrate. In the vertical type, a substrate is horizontally placed, then gas is introduced from the top or bottom of a reactor, and a Si-containing film is formed on the substrate. In the cylindrical type, where a substrate has a cylindrical shape, gas is introduced from the top or bottom of a reactor, and a Si-containing film is formed on the substrate while the substrate is being rotated. In the continuous type, gas is introduced from the top of a reactor to a substrate placed on a conveyor belt, and a Si-containing film is formed on the substrate. In the tubular type, a substrate is placed between paired tubular heaters, and gas is suctioned using a vacuum apparatus to form a Si-containing film on the substrate. In the low-pressure CVD method, the pressure inside the reactor is reduced using a vacuum pump, and a pump such as a mechanical booster pump (MBP) or a turbo molecular pump (TMP) may also be used in combination.

The reactor 7 itself may not be provided with a heating device, and the reactor 7 itself may be provided with a cooling device. The temperature of the reactor 7 is not particularly limited as long as the substrate satisfies a predetermined temperature as described below.

The pressure inside the reactor 7 is preferably from 0.001 kPa to 50 kPa, more preferably from 0.005 kPa to 10 kPa, further preferably from 0.01 kPa to 5 kPa, and further more preferably from 0.1 kPa to 1 kPa as an absolute pressure.

The flow rate of the cyclic silane compound 2 introduced into the reactor 7 is preferably from 0.01 sccm to 100 sccm, more preferably from 0.04 sccm to 50 sccm, and further preferably from 0.1 sccm to 10 sccm.

The flow rate unit “sccm” stands for standard cubic centimeters per minute (standard cc/min) at 1 atm (atmospheric pressure of 1013 hPa), where the standard cubic centimeter is a value converted to 0° C.

The reactor 7 may be equipped with the inert gas introduction line 13 for dilution from the viewpoint of adjusting the concentration of the cyclic silane compound 2.

The flow rate of the inert gas (carrier gas such as argon) introduced into the reactor 7 is preferably from 0.01 sccm to 200 sccm, more preferably from 0.1 sccm to 150 sccm, further preferably from 0.5 sccm to 100 sccm, and further more preferably from 1 sccm to 100 sccm as a total flow rate of the inert gas for dilution and the inert gas for bubbling.

In the supply line 5, the ratio of the amount (volume basis) of the inert gas to the amount of the silane compound, i.e., the ratio of “the amount of inert, gas/the amount of silane compound” (preferably. “the flow rate of the inert gas for bubbling/the flow rate of the gas containing cyclic silane compound”) is preferably from 5 to 1500, more preferably from 10 to 1200, further preferably from 15 to 900, and further more preferably from 20 to 600.

When the ratio is within the range, the step coverage of the silicon film formed on the substrate including irregularities may be further improved.

The ratio of the amount (volume) of the inert gas supplied to the reactor to the amount of the silane compound supplied to the reactor, i.e., the ratio of “the amount of inert gas/the amount of silane compound” (for example, the sum of the flow rate of the inert, gas for bubbling and the flow rate of the inert gas for dilution/the flow rate of the gas containing cyclic silane compound) is preferably from 5 to 2000, more preferably from 10 to 1700, further preferably from 15 to 1400, and further more preferably from 20 to 1100.

When the ratio is within the above range, the cyclic silane compound in the state of uniform diffusion over the entire substrate including irregularities can react, and the step coverage can be improved.

After the cyclic silane compound 2 is supplied to the reactor 7, a known treatment may be conducted before the cyclic silane compound 2 reaches the substrate 8, so that the cyclic silane compound 2 can uniformly reach the substrate 8. For example, the cyclic silane compound 2 may pass through a meshed layer in the treatment.

The substrate 8 is, for example, a silicon substrate or a silicon substrate including the following film formed on its surface. Examples of the film formed on the silicon substrate include a silicon oxide film, metal oxide film (examples of the metal include hafnium, iridium, titanium, zirconium, and tantalum), silicon nitride film, metal nitride film (examples of the metal include tungsten, titanium, zirconium, and tantalum), and metal film (examples of the metal include copper, iridium, titanium, zirconium, and tantalum). The film may be a single film, or a patterned film formed by a mixture of multiple types of films. The substrate 8 preferably has a plate-shape including irregularities, or a plate-shape.

The predetermined shape of the substrate 8 may be or may not be a flat shape, and the above predetermined shape may include trench-shaped or hole-shaped structure with irregularities. The trench-shaped structure has a predetermined depth, and the width of the opening at the surface of the substrate is preferably the same as the width of the opening in the deeper part of the substrate. The width of the opening at the surface of the substrate and the width of the opening in the deeper part of the substrate may be different, for example, the width of the opening may be larger at the surface of the substate with a decrease in the width of the opening toward the depth of the substrate. The hole-shaped structure may have a cylindrical or polygonal shape (for example, triangular or quadrangular shape).

When the substrate 8 includes trench-shaped structure, the width of the opening is, for example, from 10 nm to 3000 nm, preferably from 20 nm to 2000 nm, and more preferably from 50 nm to 1000 nm.

When the substrate 8 includes hole-shaped structure, the width or an equivalent circle diameter is, for example, from 10 nm to 300 nm, preferably from 20 nm to 2000 nm, and more preferably from 50 nm to 1000 nm.

The trench-shaped or hole-shaped structure may have the depth that satisfies the following aspect ratio, and the depth is preferably from 1 nm to 50000 nm, more preferably from 2 nm to 40000 nm, further preferably from 3 nm to 30000 nm, and further more preferably from 5 nm to 20000 nm.

The trench-shaped or hole-shaped structure has the aspect ratio (the aspect ratio is “depth/width of opening” for trench-shaped structure, and the aspect ratio is “depth/opening diameter” for hole-shaped structure, with the proviso that a short diameter of an opening will be used when the hole is not a perfect circle) of preferably 30 or less, more preferably 25 or less, further preferably 20 or less, and further more preferably 15 or less, and preferably 0.1 or more, 0.2 or more, and 0.5 or more from the viewpoint of improving coverage.

The heating temperature of the substrate 8 is preferably from 200° C. to 600° C., more preferably from 250° C. to 550° C. from the viewpoint of the stability of the resulting silicon film, and further preferably 520° C. or lower, further more preferably 500° C. or lower, and particularly preferably 480° C. or lower. In the present invention, the silicon film having high uniformity of film thickness or high step coverage can be formed by heating the substrate alone.

The reaction time (deposition time) in the reactor 7 may be selected according to the heating temperature of the substrate used, the flow rate of the inert gas supplied to the reactor, and the flow rate of a gas containing the cyclic silane compound. The reaction time is preferably from 10 minutes to 24 hours, more preferably from 15 minutes to 18 hours, and further preferably from 30 minutes to 12 hours.

The growth rate of the silicon film 12 is preferably 0.05 nm/min or more, more preferably 0.1 nm/min or more, further preferably 0.5 nm/min or more, and preferably 100 nm/min or less, more preferably 10 nm/min or less, and further preferably 5 nm/min or less. Inside the reactor, the convection and the stagnation are preferably suppressed to increase the growth rate of the film or improve the uniformity of film thickness, and the flow inside the reactor is laminar. i.e., the fluid flow line is preferably parallel to the supply line axis constantly. To predict the fluid flow, the Reynolds number “Re” is used and is represented by the following general formula.

$$Re = du ρ / η ( d \text{:} pipe diameter ( m ) , u \text{:} flow speed ( m / s ) , ρ \text{:} density ( kg / {cm}^{3} ) , η \text{:} viscosity of Newtonian fluid ( kg / m \cdot s ) )$$

When the value of Re is lower, the generation of the turbulence can be reduced, and plurality of gas introduction lines may be installed for the purpose.

The film thickness of the silicon film 12 formed on the substrate according to the production method of the present invention may be measured by any method with a spectroscopic ellipsometer, stylus type step thickness meter, scanning electron microscope (SEM), or transmission electron microscope (TEM), without particular limitation. Particularly, when the thickness of the film formed on the substrate including trench-shaped or hole-shaped structure with irregularities is measured, the substrate is processed in an appropriate manner using focused ion beam (FIB) and then a cross section is cut out by FIB, and the film thickness is measured from images obtained by using an electron microscope, such as a SEM or TEM.

The silicon film 12 formed on the substrate according to the production method of the present invention has uniformity of film thickness.

The characteristics of the silicon film are evaluated based on either the uniformity of film thickness distribution (when the silicon film has a thickness of 3.0 nm or more) or the uniformity of film thickness (when the silicon film has a thickness of less than 3.0 nm) depending on the silicon film thickness.

The uniformity of film thickness distribution is calculated from average film thickness ±{(maximum film thickness−minimum film thickness)/(maximum film thickness+minimum film thickness)}×100. The part “±{(maximum film thickness−minimum film thickness)/(maximum film thickness+minimum film thickness)}×100” represents an error of the uniformity of film thickness distribution.

The uniformity of film thickness distribution is within ±10% (from −10% to +10%), preferably within ±9% (from −9% to +9%), more preferably within ±8% (from −8% to +8%), further preferably within ±7% (from −7% to +7%), for example, within ±0.01% (from −0.01% to +0.01%), preferably within ±0.02% (from −0.02% to +0.02%), and more preferably within ±0.03% (from −0.03% to +0.03%).

In the present invention, the uniformity of film thickness distribution is represented to be, for example. “within ±10%”, and this represents the range of from −10% to +10%. This also applies to cases with other numerical values.

The uniformity of film thickness is represented by (maximum film thickness−minimum film thickness).

The uniformity of film thickness of the silicon film 12 (the difference between maximum and minimum film thicknesses) is within ±0.3 nm (from −0.3 nm to +0.3 nm), preferably within ±0.29 nm (from −0.29 nm to +0.29 nm), more preferably within ±0.28 nm (from −0.28 nm to +0.28 nm), and further preferably within ±0.27 nm (from −0.27 nm to +0.27 nm). A difference as close to zero as possible is preferred, and the uniformity of film thickness is preferably within ±0.01 nm (from −0.01 nm to +0.01 nm) or within ±0.02 nm (from −0.02 nm to +0.02 nm).

In the present invention, the uniformity of film thickness is represented to be, for example. “within ±0.3 nm”, and this means the range of from −0.3 nm to +0.3 nm. This also applies to cases with other numerical values.

After the formation of the silicon film 12, the residual liquid material or the vaporized gas may be completely removed from the raw material tank 1 and a pipe such as the supply line 5, which are used in the method for producing the silicon film of the present invention, by cycle purging, depressurizing and/or heating, thereby enabling safe and repeated formation of the silicon film 12.

### 2. Silicon Film

The present invention also includes the silicon film 12 produced according to the above method for producing the silicon film. The silicon film 12 produced according to the above method for producing the silicon film can be formed by high speed deposition and low-temperature deposition, thereby achieving high step coverage and the formation of the film with high purity. Hence, the silicon film 12 can be suitably used at any place requiring the film, for example, in semiconductors and electronic devices such as thin-film transistors and integrated circuits, regardless of whether the silicon film is an amorphous silicon film or a polycrystalline silicon film.

In one embodiment, the silicon film 12 of the present invention is a silicon film formed from the cyclic silane compound, and the film has the uniformity of film thickness of from −0.3 nm to +0.3 nm when the silicon film has the thickness of 0.5 nm or more and less than 3.0 nm, or the film has the uniformity of film thickness distribution of from −10% to +10% when the silicon film has the thickness of 3.0 nm or more.

The silicon film 12 may be formed on a flat substrate, and the silicon film formed on the flat substrate may have the same uniformity of film thickness as described above. If monosilane or disilane is used, a silicon film having a thickness of from 0.5 nm to 3.0 nm may not be obtained.

The silicon film 12 has a thickness of preferably from 0.5 nm to 2000 nm, more preferably from 0.6 nm to 1000 nm, further preferably from 0.7 nm to 500 nm, further more preferably from 0.8 nm to 200 nm, and particularly preferably from 1 nm to 100 nm.

The silicon film 12 preferably has a size (area) corresponding to a 30 mm to 300 mm wafer.

The silicon film 12 may have a predetermined refractive index, and the refractive index is, for example, from 4.0 to 4.7, preferably from 4.1 to 4.6, and more preferably from 4.2 to 4.5 for the amorphous silicon film.

In one embodiment, the silicon film 12 of the present invention is the silicon film formed from the cyclic silane compound, and has the ratio (A/B) of the silicon film thickness A on the sidewall at the depth of ¼t to the silicon film thickness B on the sidewall at the depth of ¾t is from 0.8 to 1.2 when the silicon film formed on the substrate including trench-shaped or hole-shaped structure with irregularities and a trench or hole has the depth of 0/t at, the bottom and the depth of t/t at the upper edge.

As shown in FIG. 2, the ratio (A/B) of the silicon film thickness A on the side wall at the depth of ¼t to the silicon film thickness B on the side wall at the depth of ¾t is from 0.8 to 1.2, preferably 0.82 or more, more preferably 0.84 or more, further preferably 0.86 or more, further more preferably 0.88 or more, still more preferably 0.90 or more, particularly preferably 0.92 or more, and preferably 1.10 or less, more preferably 1.05 or less, and further preferably 1.00 or less from the viewpoint of step coverage, when the substrate 8 includes irregularities (trench-shaped structure), the silicon film 12 is formed on such a substrate 8, and a trench has the depth of 0/t at the bottom and the depth of t/t, at the upper edge.

Also, the step coverage may be evaluated from the ratio between the thicknesses of the silicon film formed at the bottom of the trench and the silicon film formed on a substrate without, a trench, and the ratio may satisfy approximately 1.

The thickness of the silicon film 12 formed on the substrate including irregularities is preferably from 0.5 nm to 2000 nm, more preferably from 1 nm to 1000 nm, further preferably from 2 nm to 500 nm, and further more preferably from 3 nm to 100 nm. Preferably, the film thickness is measured by the above described method and is an average of readings from two or more points.

Recent miniaturization of semiconductors has strongly required uniformity and thinning of a deposited film. However, the use of, for example, monosilane and disilane, and a substrate including irregularities (trench-shaped structure) as shown in FIG. 2 results in the ratio (A/B) of the silicon film thickness A on the side wall at the dept of ¼t to the silicon film thickness B on the side wall at the dept of ¾t of less than 0.8 as described above, and a silicon film with satisfactory uniformity cannot be obtained.

When the silicon film 12 of the present invention is an amorphous (non crystalline) silicon film, the film may be crystallized, if needed. Various annealing apparatuses may be used for the crystallization, and a crystalline silicon film (polycrystalline silicon film) can be obtained, for example, by a method in which the surface of a film is heated at a high temperature (a lamp annealing system) or by a method in which laser annealing treatment is conducted. The annealing treatment is preferably conducted in a nitrogen gas atmosphere, and may be conducted with the use of hydrogen gas in combination.

When the silicon film 12 of the present invention is heated at a high temperature to be crystallized, the temperature is preferably 600° C. or higher, more preferably 650° C. or higher, and further preferably 700° C. or higher. Considering the damage to the substrate caused by heating, the temperature is preferably 1200° C. or lower, and more preferably 1000° C. or lower.

The crystalline silicon film thus obtained may be examined by, for example. Raman spectroscopy, infrared spectroscopy, or X-ray spectroscopy to confirm the degree of crystallinity, and the crystalline silicon film may have a predetermined peak position and a predetermined full width at half maximum determined by Raman spectroscopy.

Specifically, it is preferable that the crystalline silicon film satisfies that a full width at half maximum of a Raman spectrum peak at a peak position in the range of from 510 cm⁻¹ to 5:30 cm⁻¹ (in particular, around 520 cm⁻¹) is 3 cm⁻¹ or more and 10 cm⁻¹ or less when measured by laser Raman spectroscopy.

The value of the full width at half maximum is more preferably 3 cm⁻¹ or more and 9 cm⁻¹ or less, and further preferably 4 cm⁻¹ or more and 8 cm⁻¹ or less. The silicon film has significantly high crystallinity when the value of the full width at half maximum is within the above range.

Regarding the measurement conditions for laser Raman spectroscopy, the conditions follow the description in EXAMPLES.

After the heating of the silicon film at 600° C. or higher, the peak of Raman spectrum appears at a peak position of around 520 cm⁻¹. The peak value originates from Si—Si bond, and the silicon film before heating at 600° C. or higher has a peak of Raman spectrum which appears at a wavenumber of lower than 520 cm⁻¹.

In addition, the full width at half maximum at the peak position of around 520 cm⁻¹ is significantly narrow, indicating that the degree of crystallinity is high. Conversely, when a peak appears at a wavenumber of lower than 520 cm⁻¹, a full width at half maximum cannot be detected, or a full width at half maximum over a wide range is observed even if the full width at half maximum is detected, indicating that the degree of crystallinity is low.

The silicon film 12 of the present invention has the full width at half maximum of a peak of Raman spectrum at around 520 cm⁻¹ that is preferably smaller than the full width at, half maximum of a peak of Raman spectrum at a wavenumber of lower than 520 cm⁻¹.

The silicon film 12 of the present invention may include an amorphous silicon film, a crystalline silicon film, and a composite of an amorphous silicon film and a crystalline silicon film. The composite may include a laminate of an amorphous silicon film and a crystalline silicon film and an amorphous silicon film on which crystalline silicon is formed.

The silicon film 12 of the present invention preferably exclude an epitaxial film formed by using etching gas.

The silicon film 12 of the present invention can be widely used as a component for forming thin-film transistors for semiconductors and is expected to be used in various applications such as polysilicon electrodes for three-dimensional mounting. Furthermore, the silicon film 12 of the present invention can be used in various fields, for example, electronic devices such as a solar cell, and display components.

The present application claims benefit of priority to Japanese Patent Application No. 2022-104744 filed on Jun. 29, 2022. The entire contents of the specification of Japanese Patent Application No. 2022-104744 riled on Jun. 29, 2022 area incorporated herein by reference.

### EXAMPLES

Hereinafter, the present invention will be more specifically described with Examples, and the scope of the present invention is not limited by Examples. The present invention can be carried out with modifications within a range conforming to the gist described above and/or below, all of which are included in the technical scope of the present invention.

### <Evaluation of Uniformity of Film Thickness Distribution and Uniformity of Film Thickness of Silicon Film>

The silicon films formed were evaluated according to the following methods.
FIB method: After embedding a resist film for the protection of a sample top surface, a tungsten film was coated by FIB, and a micro sample was extracted using a FIB micro sampling unit. The extracted micro sample was then sectioned through FIB processing at a thickness observable by TEM.
Systems used for sample preparation: Focused ion and electron beam system (nanoDUET NB5000), manufactured by Hitachi High-Tech
   : Dual beam (FIBiSEM) system Nova200, manufactured by FEI Company Japan Ltd.
Acceleration voltage: 30 kV, 5 kV
Ion source: Ga

Using the sample thus obtained, the cross-section of the substrate was observed with a transmission electron microscope (TEM) under the following conditions, and the film thickness was determined.
TEM systems: Field emission transmission electron microscope HF-2200, manufactured by Hitachi High-Tech
   : One View (Model 1095), manufactured by Gatan. Inc.
Acceleration voltage: 200 kV

$$Uniformity of film thickness distribution = average film thickness \pm \{ ( maximum film thickness - minimum film thickness ) / ( maximum film thickness + minimum film thickness ) \} \times 100$$

$$Uniformity of film thickness = ( maximum film thickness - minimum film thickness )$$

### Measurement Conditions for Haman Spectroscopy

Measuring apparatus: a micro-Raman spectrometer NRS-3100, manufactured by JASCO Corporation
Measurement methods: micro-Raman spectroscopy, with the use of 532 nm of laser, and an objective lens with 100× magnification, CCD acquisition time of 20 seconds, and accumulation of 4 scans

### Example 1

As shown in FIG. 1, a silicon film was produced using a silicon film forming system (cold-wall type thermal CVD system 15).

As the cyclic silane compound 2, cyclohexasilane (with a purity of 99% as determined by gas chromatography) was filled in the raw material tank 1. Subsequently, the raw material tank 1 and the supply line 5 were heated to 30° C. the pressure of the raw material tank 1 was reduced to 6.5 kPa, the pressure of the reactor 7 was reduced to 400 Pa, and an inert gas (argon gas) was supplied at a flow rate of 14 sccm from the inert gas introduction line 3 for bubbling connected to the raw material tank 1 to supply the cyclic silane compound 2 to the reactor 7 (the flow rate of cyclohexasilane contained in the inert gas (argon gas) supplied to the reactor 7 from the supply line 5 was 0.14 stem). From the inert, gas introduction line 13 for dilution, the inert gas (argon gas) was supplied at a flow rate of 21 stem. The substrate 8 in the reactor 7 was a silicon substrate including a trench (depth: 10000 nm, width: 800 nm). The substrate 8 was heated to 500° C. by the substrate heater 9, and a silicon film 12 was formed in 5 hours. The silicon film 12 thus obtained was an amorphous silicon film.

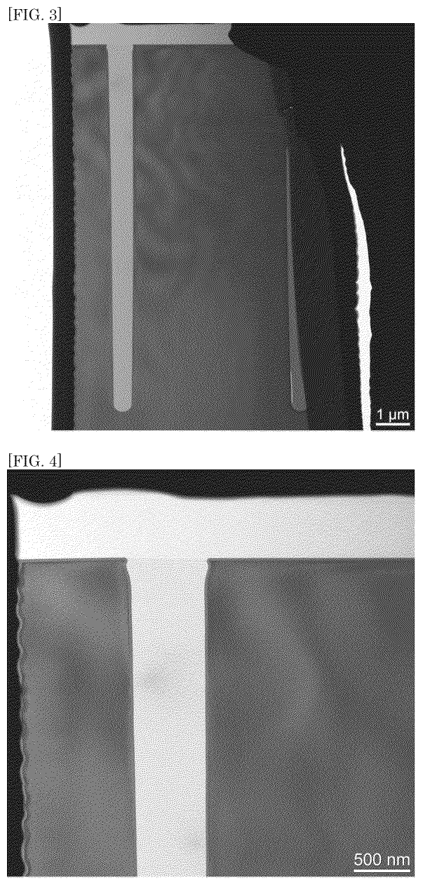

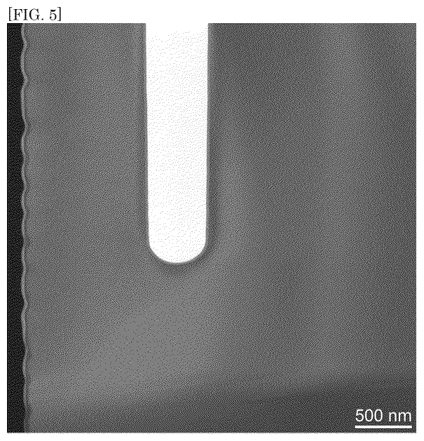

The silicon film 12 thus obtained and the substrate 8 were measured by cross-sectional TEM and the results are shown in FIGS. 3 to 5. When the trench had the depth of 0/t at the bottom and the depth of t/t at the upper edge, the silicon film thickness A on the side wall of the trench at the depth of ¼t was 25.4 nm and the silicon film thickness B on the side wall of the trench at the depth of ¾t was 25.3 nm, resulting in the ratio A/B of 1.00, in the evaluation of the uniformity of film thickness distribution by the method described above. The silicon film 12 was formed with the uniformity of film thickness distribution of from −10% to +10% throughout the film. FIG. 5 is a TEM image at the depth of ¼t and FIG. 4 is a TEM image at the depth of ¾t.

### Example 2

A silicon film 12 was formed under the same conditions as Example 1 except that the pressure of the raw material tank 1 was reduced to 1.9 kPa, an inert gas (argon gas) was supplied at a flow rate of 1 sccm from the inert gas introduction line 3 for bubbling connected to the raw material tank 1, and the inert gas (argon gas) was supplied at a flow rate of 34 sccm from the inert gas introduction line 13 for dilution (the flow rate of cyclohexasilane contained in the inert, gas (argon gas) supplied to the reactor 7 from the supply line 5 was 0.04 sccm). The silicon film 12 thus obtained was an amorphous silicon film.

As a result of the cross-sectional TEM measurement of the obtained silicon film 12, it was found that the silicon film thickness A on the side wall of the trench at the depth of ¼t was 17.1 nm, the silicon film thickness B on the side wall of the trench at the depth of ¾t was 18.4 nm, and the ratio A/B was 0.93, when the trench had the depth of 0/t, at the bottom and the depth of t/t at the upper edge. The silicon film 12 was formed with the uniformity of film thickness distribution of from −10% to +10% throughout the film.

### Example 3

A silicon film was formed under the same conditions as Example 1 except that the pressure of the reactor 7 was reduced to 533 Pa and an inert gas (argon gas) was supplied at a flow rate of 36 sccm from the inert gas introduction line 13 for dilution (the flow rate of cyclohexasilane contained in the inert gas (argon gas) supplied to the reactor 7 from the supply line 5 was 0.14 sccm). The silicon film 12 thus obtained was an amorphous silicon film.

As a result of the cross-sectional TEM measurement, of the obtained silicon film, it was found that the silicon film thickness A on the side wall of the trench at the depth of ¼t was 31.9 nm, the silicon film thickness B on the side wall of the trench at the depth of ¾t was 34.3 nm, and the ratio A/B was 0.93, when the trench had the depth of 0/t at the bottom and the depth of t/t at the upper edge. The silicon film 12 was formed with the uniformity of film thickness distribution of from −10% to +10% throughout the film.

### Example 4

A silicon film 12 was formed under the same conditions as Example 1 except that a flat, silicon substrate including a thermal oxide film (film thickness: 100 nm) was used as a substrate. The silicon film thus obtained was subjected to laser Raman spectroscopy and the resulting Raman spectrum included a broad peak characteristic of an amorphous silicon film (peak position: 477.7 cm⁻¹).

The above amorphous silicon film formed from cyclohexasilane was heated using a lamp annealing system (RTA) under the condition of 800° C. for 30 seconds. The Raman spectra of the obtained film showed a sharp peak at a peak position of 519.7 cm⁻¹ with a full width at half maximum of the peak of 8 cm⁻¹, indicating that the resulting film was highly crystalline silicon film (polycrystalline silicon film).

### Comparative Example 1

A silicon film 12 was formed using the silicon film forming apparatus (cold-wall type thermal CVU system 15) as shown in FIG. 1 (a high-pressure cylinder of disilane was used instead of the raw material tank 1).

Disilane was supplied to the reactor 7 at a flow rate of 5 sccm using a high-pressure cylinder of disilane, instead of using the raw material tank 1. Inert gas (argon gas) was supplied at a flow rate of 21 sccm from the inert gas introduction line 13 for dilution. The substrate 8 in the reactor 7 was a silicon substrate including a trench (depth: 10000 nm, width: 800 nm). The substrate 8 was heated to 500° C. by the substrate heater 9, and a silicon film 12 was formed in 4 hours of film deposition. The silicon film 12 thus obtained was an amorphous silicon film.

As a result of the cross-sectional TEM measurement of the obtained silicon film 12 and the substrate 8, it was found that the silicon film thickness A on the side wall of the trench at the depth of ¼t was 23.3 nm, the silicon film thickness B on the side wall of the trench at the depth of ¾t was 31.0 nm, and the ratio A/B was 0.75, when the trench had the depth of 0/t at the bottom and the depth of t/t at the upper edge. The silicon film 12 was not formed with the uniformity of film thickness distribution of from −10% to +10% throughout the film.

TABLE 1

| | | | | | | | | | Comparative | |
|---|---|---|---|---|---|---|---|---|---|---|
| | Example 1 | | Example 2 | | Example 3 | | Example 4 | | Example 1 | |
| Raw material tank temperature | 30° | C. | 30° | C. | 30° | C. | 30° | C. | — | |
| Raw material tank pressure | 6.5 | kPa | 1.9 | kPa | 6.5 | kPa | 6.5 | kPa | — | |
| Supply line temperature | 30° | C. | 30° | C. | 30° | C. | 30° | C. | — | |
| Reactor pressure | 400 | Pa | 400 | Pa | 533 | Pa | 400 | Pa | 400 | Pa |
| Flow rate of inert gas for bubbling | 14 | sccm | 1 | sccm | 14 | sccm | 14 | sccm | — | |
| Flow rate of gas containing silane compound | 0.14 | sccm | 0.04 | sccm | 0.14 | sccm | 0.14 | sccm | 5 | sccm |
| Flow rate of inert gas for dilution | 21 | sccm | 34 | sccm | 36 | sccm | 21 | sccm | 21 | sccm |
| Flow rate of inert gas for bubbling/ | 100 | | 25 | | 100 | | 100 | | | |
| flow rate of gas containing silane compound | | | | | | | | | | |
| Sum of flow rates of inert gas/ | 250 | | 875 | | 357 | | 250 | | 4.2 | |
| flow rate of gas containing silane compound | | | | | | | | | | |
| Substrate | Silicon | | Silicon | | Silicon | | Silicon substrate | | Silicon | |
| | substrate | | substrate | | substrate | | including a | | substrate | |
| | | | | | | | thermal oxide film | | | |
| Ratio of depth/width | 12.5 | | 12.5 | | 12.5 | | — | | 12.5 | |
| Substrate temperature | 500° | C. | 500° | C. | 500° | C. | 500° | C. | 500° | C. |

| | | | | | | | | | |
|---|---|---|---|---|---|---|---|---|---|
| A: Silicon film thickness at a depth of ¼ t | 25.4 | nm | 17.1 | nm | 31.9 | nm | — | 23.3 | nm |
| B: Silicon film thickness at a depth of ¾ t | 25.3 | nm | 18.4 | nm | 34.3 | nm | — | 31.0 | nm |

| | | | | | |
|---|---|---|---|---|---|
| A/B | 1.00 | 0.93 | 0.93 | — | 0.75 |
| Uniformity of film thickness | From −10% | From −10% | From −10% | — | Outside the range of |
| | to +10% | to +10% | to +10% | | from −10% to +10% |

### EXPLANATION OF LETTERS OR NUMERALS

1: Raw material tank
2: Cyclic silane compound
3: Inert gas introduction line for bubbling
4: Flow controller
5: Supply line
6: Pressure controller
7: Reactor
8: Substrate
9: Substrate heater
10: Outlet
11: Vacuum pump
12: Silicon film
13: Inert gas introduction line for dilution
14: Pressure controller
15: Cold-wall type thermal CVD system

1. A method for producing a silicon film, comprising the steps of:
heating a substrate inserted into a reactor of a cold-wall type thermal CVD system;
supplying a cyclic silane compound to the reactor; and
forming the silicon film on the substrate.

2. The method according to claim 1, wherein the cyclic silane compound and an inert gas are supplied to the reactor, and a volume of the inert gas supplied to the reactor is at least five times greater than a volume of the cyclic silane compound.

3. The method according to claim 1, wherein the silicon film is formed with uniformity of film thickness distribution of from −10% to +10% on a substrate including trench-shaped or hole-shaped irregularities.

4. The method according to claim 3, wherein the trench-shaped or hole-shaped irregularities have an aspect ratio of 30 or less.

5. The method according to claim 1, wherein the substrate is heated at a heating temperature of from 200° C. to 600° C.

6. The method according to claim 1, wherein the reactor has a pressure inside the reactor of from 0.01 kPa to 50 kPa.

7. The method according to claim 1, wherein the cyclic silane compound filled in a container is vaporized and then supplied to the reactor.

8. The method according to claim 1, wherein the cyclic silane compound contains cyclopentasilane or cyclohexasilane.

9. The method according to claim 1, wherein the silicon film is heated at 600° C. or higher.

10. A silicon film comprising a cyclic silane compound, wherein the silicon film has uniformity of film thickness of from −0.3 nm to +0.3 nm when the silicon film has a thickness of 0.5 nm or more and less than 3.0 nm, or the silicon film has uniformity of film thickness distribution of from −10% to +10% when the silicon film has a thickness of 3.0 nm or more.

11. A silicon film comprising a cyclic silane compound, wherein the silicon film is formed on a substrate including trench-shaped or hole-shaped structure with irregularities, and
a ratio (A/B) of a silicon film thickness A on a sidewall at a depth of ¼t to a silicon film thickness B on a sidewall at a depth of ¾t is from 0.8 to 1.2 when a trench or hole has a depth of 0/t at a bottom and a depth of t/t at an upper edge.

12. The silicon film according to claim 11, wherein the substrate including the irregularities has an aspect ratio of 30 or less.

13. The silicon film according to claim 10, wherein a full width at half maximum of a Raman spectrum peak in the range of from 510 cm⁻¹ to 530 cm⁻¹ is 3 cm⁻¹ or more and 10 cm⁻¹ or less when measured by laser Raman spectroscopy.

14. The method according to claim 2, wherein the silicon film is formed with uniformity of film thickness distribution of from −10% to +10% on a substrate including trench-shaped or hole-shaped irregularities.

15. The method according to claim 2, wherein the substrate is heated at a heating temperature of from 200° C. to 600° C.

16. The method according to claim 2, wherein the reactor has a pressure inside the reactor of from 0.01 kPa to 50 kPa.

17. The method according to claim 2, wherein the cyclic silane compound filled in a container is vaporized and then supplied to the reactor.

18. The method according to claim 2, wherein the cyclic silane compound contains cyclopentasilane or cyclohexasilane.

19. The method according to claim 2, wherein the silicon film is heated at 600° C. or higher.

20. The silicon film according to claim 11, wherein a full width at half maximum of a Raman spectrum peak in the range of from 510 cm⁻¹ to 530 cm⁻¹ is 3 cm⁻¹ or more and 10 cm⁻¹ or less when measured by laser Raman spectroscopy.
